(19) United States
(12) Patent Application Publication
(10) Pub. No.: US 2025/0140668 A1
(43) Pub. Date: May 1, 2025

(54) SEMICONDUCTOR PACKAGE

(71) Applicant: Samsung Electronics Co., Ltd., Suwon-si (KR)

(72) Inventors: Hyunwoong HAN, Suwon-si (KR); Junhyeong PARK, Suwon-si (KR); Young Kwan SEO, Suwon-si (KR); Kyungtae KIM, Suwon-si (KR)

(73) Assignee: Samsung Electronics Co., Ltd., Suwon-si (KR)

(21) Appl. No.: 18/672,313

(22) Filed: May 23, 2024

(30) Foreign Application Priority Data
Oct. 31, 2023 (KR) 10-2023-0147853

(51) Int. Cl. H01L 23/498; H01L 23/00; H01L 25/065

(52) U.S. Cl. CPC H01L 23/49822; H01L 23/49838; H01L 24/08; H01L 24/16; H01L 25/0657; H01L 2224/08146; H01L 2224/08225; H01L 2224/16146; H01L 2224/16225; H01L 2225/0651; H01L 2225/06513; H01L 2924/182; H01L 2924/351

(57) ABSTRACT

A semiconductor package includes a first redistribution substrate comprising first redistribution patterns and first redistribution insulating layers covering the first redistribution patterns, a conductive post on the first redistribution substrate, extending in a direction perpendicular to a top surface of the first redistribution substrate and electrically connected to a corresponding one of the first redistribution patterns, a first semiconductor chip on the first redistribution substrate and laterally spaced apart from the conductive post, and a second redistribution substrate on the conductive post and the first semiconductor chip and comprising second redistribution patterns. The conductive post is electrically connected to a corresponding one of the second redistribution patterns. A top surface of the conductive post faces the second redistribution substrate. The conductive post includes contact holes extending from the top surface of the conductive post into the conductive post. The corresponding second redistribution pattern fills the contact holes.

### CROSS-REFERENCE TO RELATED APPLICATIONS

This U.S. non-provisional patent application claims priority under 35 U.S.C. § 119 to Korean Patent Application No. 10-2023-0147853, filed on Oct. 31, 2023, in the Korean Intellectual Property Office, the entire contents of which are hereby incorporated by reference.

### BACKGROUND

The present disclosure relates to a semiconductor package and a method of manufacturing the same, and more particularly, to a semiconductor package, in which semiconductor chips and electronic elements are mounted, and a method of manufacturing the same.

An integrated circuit chip may be realized in the form of a semiconductor package so as to be appropriately applied to an electronic product. In a typical semiconductor package, a semiconductor chip may be mounted on a printed circuit board (PCB) and may be electrically connected to the PCB through bonding wires or bumps. Small, light and multi-functional electronic products have been desired with the development of the electronic industry, and thus various techniques have been studied to improve reliability and/or integration density of a semiconductor package and/or to reduce a size of a semiconductor package.

### SUMMARY

Example embodiments of the inventive concepts may provide a semiconductor package having improved or excellent reliability and a method of manufacturing the same.

Example embodiments of the inventive concepts may also provide a semiconductor package capable of more easily reducing a size thereof and of more easily improving an integration density thereof, and a method of manufacturing the same,

In example embodiments, a semiconductor package may include a first redistribution substrate comprising first redistribution patterns and first redistribution insulating layers covering the first redistribution patterns, a conductive post on the first redistribution substrate, extending in a direction perpendicular to a top surface of the first redistribution substrate and electrically connected to a corresponding one of the first redistribution patterns, a first semiconductor chip on the first redistribution substrate and laterally spaced apart from the conductive post, and a second redistribution substrate on the conductive post and the first semiconductor chip and comprising second redistribution patterns. The conductive post may be electrically connected to a corresponding second redistribution pattern of the second redistribution patterns. A top surface of the conductive post may face the second redistribution substrate. The conductive post may include contact holes extending from the top surface of the conductive post into the conductive post. The corresponding second redistribution pattern may fill the contact holes.

In example embodiments, a semiconductor package may include a first redistribution substrate comprising first redistribution patterns and first redistribution insulating layers covering the first redistribution patterns, conductive posts on the first redistribution substrate, vertically extending from the first redistribution substrate and electrically connected to the first redistribution patterns, a first semiconductor chip on the first redistribution substrate, and a second redistribution substrate on the conductive posts. The second redistribution substrate may include second redistribution patterns and second redistribution insulating layers covering the second redistribution patterns. The second redistribution patterns may be electrically connected to the conductive posts. The second redistribution patterns may include via patterns in contact with a corresponding conductive post. Each of the via patterns may include protruding portions extending into each of the conductive posts.

### BRIEF DESCRIPTION OF THE DRAWINGS

FIG. 1 is a plan view illustrating a semiconductor package according to some example embodiments of the inventive concepts.

FIG. 2 is a cross-sectional view taken along a line A-A′ of FIG. 1 to illustrate a semiconductor package according to some example embodiments of the inventive concepts.

FIG. 3 is an enlarged view of a portion ‘B’ of FIG. 2 to illustrate a portion of a semiconductor package according to some example embodiments of the inventive concepts.

FIGS. 4 to 6 are cross-sectional views corresponding to the line A-A′ of FIG. 1 to illustrate a method of manufacturing a semiconductor package according to some example embodiments of the inventive concepts.

### DETAILED DESCRIPTION

Example embodiments of the inventive concepts will now be described more fully with reference to the accompanying drawings.

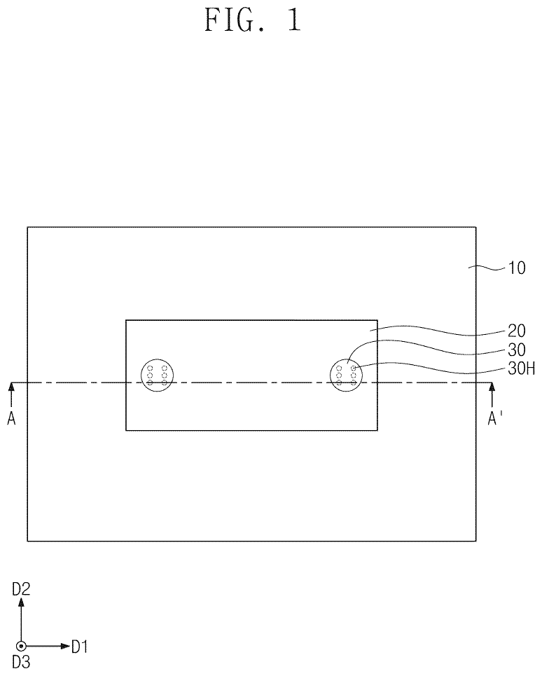

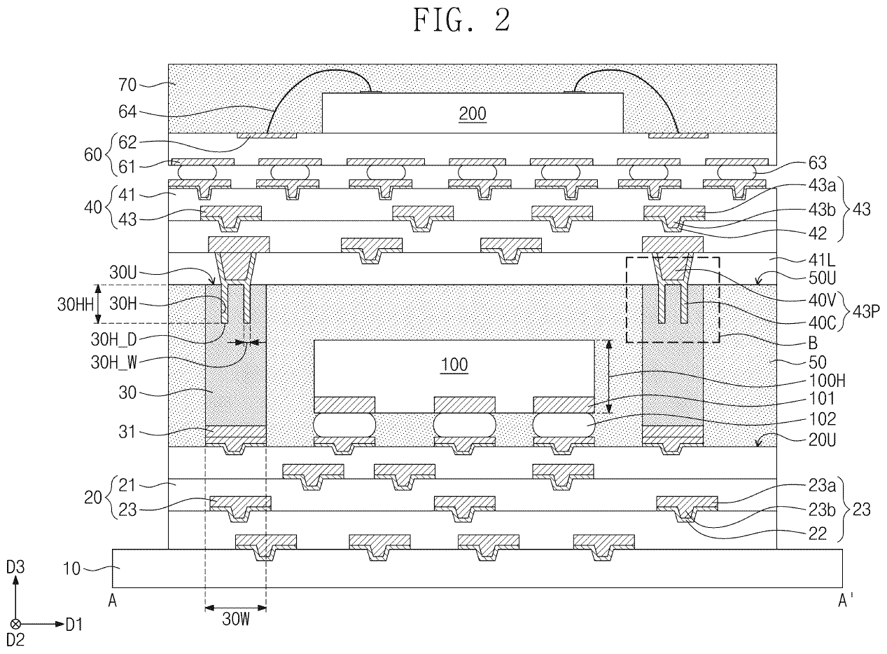

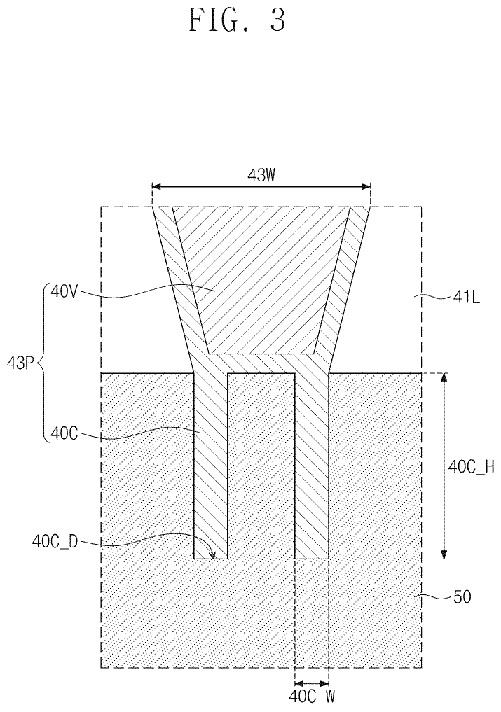

FIG. 1 is a plan view illustrating a semiconductor package according to some example embodiments of the inventive concepts. FIG. 2 is a cross-sectional view taken along a line A-A′ of FIG. 1 to illustrate a semiconductor package according to some example embodiments of the inventive concepts. FIG. 3 is an enlarged view of a portion ‘B’ of FIG. 2 to illustrate a portion of a semiconductor package according to some example embodiments of the inventive concepts.

Referring to FIGS. 1 and 2, a semiconductor package may include a lower structure 10, and a first redistribution substrate 20 extending in a first direction D1 and a second direction D2 on the lower structure 10. The lower structure 10 may include a printed circuit board, a semiconductor chip, or a semiconductor package. The first direction D1 and the second direction D2 may be parallel to a top surface 20U of the first redistribution substrate 20 and may intersect each other.

The first redistribution substrate 20 may include first redistribution patterns 23 and first redistribution insulating layers 21 covering the first redistribution patterns 23. The first redistribution patterns 23 may include first redistribution lines 23a spaced apart from each other in the first direction D1 and/or a third direction D3; and first redistribution contacts 23b and first redistribution seed patterns 22, which are connected to the first redistribution lines 23a. The first redistribution lines 23a may be electrically connected to each other through the first redistribution contacts 23b. The first redistribution patterns 23 may include a metal material (e.g., copper, titanium, and/or an alloy thereof), the first redistribution seed patterns 22 may include a conductive seed material (e.g., copper, titanium, and/or an alloy thereof), and the first redistribution insulating layer 21 may include a photosensitive polymer. The lower structure 10 may be electrically connected to the first redistribution substrate 20 through corresponding ones of the first redistribution patterns 23 (e.g., corresponding ones of the first redistribution contacts 23b). An uppermost one of the first redistribution insulating layers 21 may expose some of the first redistribution patterns 23 and may expose the first redistribution lines 23a of the some first redistribution patterns 23.

Conductive posts 30 may be disposed on the first redistribution substrate 20 and may extend in a direction (e.g., the third direction D3) perpendicular to the top surface 20U of the first redistribution substrate 20. Each of the conductive posts 30 may be a metal pillar. The conductive posts 30 may be spaced apart from each other in the first direction D1. Each of the conductive posts 30 may further include a first pad 31 connected to an end thereof. The conductive posts 30 may be electrically connected to corresponding ones of the first redistribution patterns 23 (e.g., corresponding ones of the first redistribution lines 23a) through the first pads 31. For example, the conductive posts 30 and the first pad 31 may include at least one of copper, aluminum, tungsten, titanium, tantalum, iron, or any alloy thereof. The conductive posts 30 may be electrically connected to the first redistribution substrate 20 through the first pads 31.

A top surface 30U of the conductive post 30 may include contact holes 30H extending into the conductive post 30. The contact holes 30H may be spaced apart from each other in the first direction D1 and the second direction D2. A bottommost surface 30H_D of each of the contact holes 30H may be located at a lower height than the top surface 30U of the conductive post 30 and may be located at a lower height than a top surface 50U of a molding layer 50 to be described below. For example, a vertical thickness 30HH of each of the contact holes 30H may range from 1 μm to 10 μm and may be substantially equal to or less than a vertical thickness 100H of a first semiconductor chip 100 to be described below. A ratio of the vertical thickness 30HH of each of the contact holes 30H to a width 30H_W of each of the contact holes 30H in the first direction D1 may range from 1:2 to 3:1.

A first semiconductor chip 100 may be mounted on the first redistribution substrate 20 and may be laterally spaced apart from the conductive posts 30 (e.g., in the first direction D1). In some example embodiments, the first semiconductor chip 100 may be disposed between the conductive posts 30. The first semiconductor chip 100 may include chip pads 101 disposed at its bottom surface. The vertical thickness 100H of the first semiconductor chip 100 may be substantially equal to or greater than the vertical thickness 30HH of each of the contact holes 30H. In some example embodiments, the first semiconductor chip 100 may further include connection bumps 102 on the chip pads 101. The connection bumps 102 may be disposed between the first semiconductor chip 100 and corresponding ones of the first redistribution patterns 23. The first semiconductor chip 100 may be electrically connected to the corresponding first redistribution patterns 23 through the connection bumps 102 and the chip pads 101. For example, the first semiconductor chip 100 may be a memory chip, a logic chip, an application processor (AP) chip, or a system-on-chip (SOC). The connection bumps 102 may include a conductive material and may have a solder ball shape, a bump shape, and/or a pillar shape. The first semiconductor chip 100 may be electrically connected to the corresponding first redistribution patterns 23 and thus may be electrically connected to the lower structure 10.

A molding layer 50 may be disposed on the first redistribution substrate 20. The molding layer 50 may cover the first semiconductor chip 100 and the conductive posts 30 and may fill a space between the first semiconductor chip 100 and the conductive posts 30. The top surface 50U of the molding layer 50 may be coplanar with the top surfaces 30U of the conductive posts 30. The molding layer 50 may include an adhesive insulating film (e.g., an Ajinomoto build-up film (ABF)) or an insulating polymer (e.g., an epoxy-based polymer).

A second redistribution substrate 40 may be disposed on the conductive posts 30, the molding layer 50 and the first semiconductor chip 100. The second redistribution substrate 40 may include second redistribution patterns 43 and second redistribution insulating layers 41 covering the second redistribution patterns 43. The second redistribution patterns 43 may include second redistribution lines 43a spaced apart from each other in the first direction D1 and/or the third direction D3; and second redistribution contacts 43b and second redistribution seed patterns 42, which are connected to the second redistribution lines 43a. The second redistribution lines 43a may be electrically connected to each other through the second redistribution contacts 43b. The second redistribution patterns 43 may include a metal material (e.g., copper, titanium, and/or an alloy thereof), and the second redistribution insulating layers 41 may include a photosensitive polymer.

Referring to FIGS. 2 and 3, the conductive posts 30 may be connected to corresponding second redistribution patterns (or via patterns) 43P of the second redistribution patterns 43. The corresponding second redistribution patterns 43P could be referred to as via patterns. The corresponding second redistribution patterns (or via patterns) 43P may fill the contact holes 30H. A width 43W of each of the corresponding second redistribution patterns (or via patterns) 43P in the first direction D1 may be less than a width of each of the conductive posts 30 in the first direction D1, and a lowermost second redistribution insulating layer 41L of the second redistribution insulating layers 41 may be in contact with the conductive posts 30. The corresponding second redistribution patterns (or via patterns) 43P may include contact portions 40C and via contacts 40V. The contact portions 40C may extending from the corresponding second redistribution patterns (or via patterns) 43P bottom surfaces into the conductive posts 30, and the contact portions 40C may fill the contact holes 30H. A width 40C_W of each of the contact portions 40C in the first direction D1 may be less than the width 43W of each of the corresponding second redistribution patterns (or via patterns) 43P in the first direction D1. The contact portions 40C may be spaced apart from each other in the first direction D1 and the second direction D2 to correspond to the contact holes 30H. A vertical thickness 40C_H of each of the contact portions 40C may be substantially equal to or less than the vertical thickness 100H of the first semiconductor chip 100 and may range from, for example, 1 μm to 10 μm. A bottommost surface 40C_D of each of the contact portions 40C may be located at a lower height than the top surface 30U of the conductive post 30 and may be located at a lower height than the top surface 50U of the molding layer 50.

Since the contact portions 40C fill the contact holes 30H, contact areas between the conductive posts 30 and the corresponding second redistribution patterns (or via patterns) 43P may be increased. Thus, electrical conductivity of the semiconductor package may be improved to improve reliability of the semiconductor package, and the semiconductor package may be more easily miniaturized and may be more easily highly integrated.

A thermal management system of the semiconductor package may be improved, and thermal stress of the semiconductor package may be reduced. Thus, it is possible to reduce or prevent a delamination phenomenon of one (e.g., the lowermost second redistribution insulating layer 41L) of the second redistribution insulating layers 41, which is in contact with the conductive posts 30. As a result, reliability of an interface may be improved to provide the semiconductor package with improved reliability. The second redistribution substrate 40 may be electrically connected to the conductive posts 30 through the corresponding second redistribution patterns 43 and thus may be electrically connected to the lower structure 10.

An upper substrate 60 may be disposed on the second redistribution substrate 40 and may be disposed on corresponding ones of the second redistribution patterns 43. The upper substrate 60 may include lower connection bumps 63. The lower connection bumps 63 may be disposed between the upper substrate 60 and the corresponding second redistribution patterns 43. The upper substrate 60 may be electrically connected to the second redistribution substrate 40 through the lower connection bumps 63. The lower connection bumps 63 may include a conductive material and may have a solder ball shape, a bump shape, and/or a pillar shape.

The upper substrate 60 may include first substrate pads 61 and second substrate pads 62. The first substrate pads 61 and the second substrate pads 62 may be electrically connected to each other through internal interconnection lines (not shown). The lower connection bumps 63 may be disposed on a corresponding first substrate pad 61. The upper substrate 60 may be electrically connected to the second redistribution substrate 40 through the first substrate pads 61 and the lower connection bumps 63. For example, the upper substrate 60 may be a printed circuit board, an interposer substrate, or a redistribution substrate.

A second semiconductor chip 200 may be mounted on the upper substrate 60. The second semiconductor chip 200 may be electrically connected to the second substrate pads 62 through conductive wires 64. The second semiconductor chip 200 may be electrically connected to the first semiconductor chip 100 through the upper substrate 60, the second redistribution substrate 40, the conductive posts 30 and the first redistribution substrate 20. An upper molding layer 70 may be disposed on the upper substrate 60 and may cover the second semiconductor chip 200.

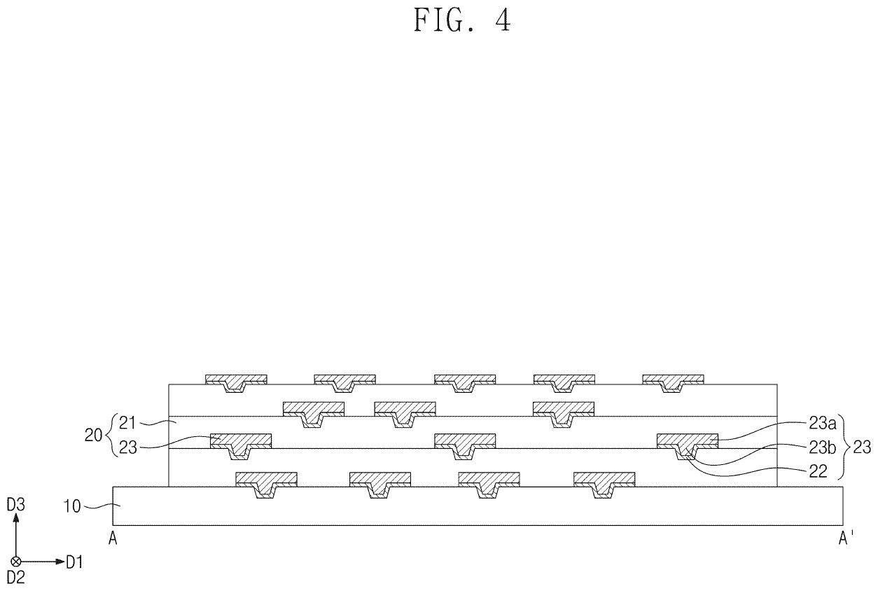

FIGS. 4 to 6 are cross-sectional views corresponding to the line A-A′ of FIG. 1 to illustrate a method of manufacturing a semiconductor package according to some example embodiments of the inventive concepts. Hereinafter, the descriptions to the same features as mentioned with reference to FIGS. 1 to 3 will be omitted for the purpose of ease and convenience in explanation.

Referring to FIG. 4, a first redistribution substrate 20 extending in the first direction D1 and the second direction D2 may be disposed on a top surface of a lower structure 10. For example, formation of the first redistribution substrate 20 may include forming first redistribution insulating layers 21 on the lower structure 10, forming first redistribution contact holes penetrating the first redistribution insulating layers 21, forming first redistribution seed patterns 22 which partially fill the first redistribution contact holes and extend onto top surfaces of the first redistribution insulating layers 21, and performing an electroplating process using the first redistribution seed patterns 22 to form first redistribution contacts 23b and first redistribution lines 23a. Each of the first redistribution contacts 23b may fill a remaining portion of each of the first redistribution contact holes, and each of the first redistribution lines 23a may extend onto a corresponding one of the first redistribution insulating layers 21.

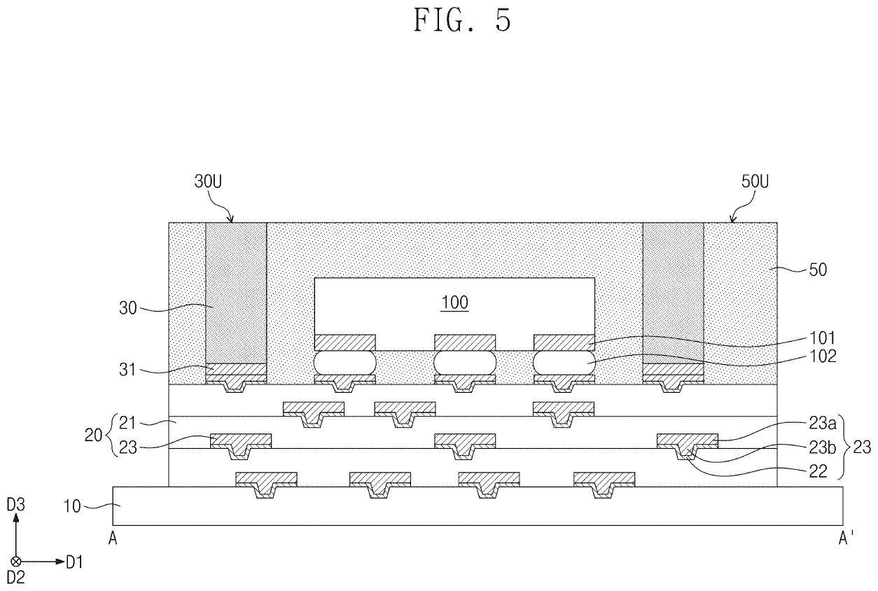

Referring to FIG. 5, conductive posts 30 may be disposed on the first redistribution substrate 20 and may extend in a direction (e.g., the third direction D3) perpendicular to a top surface of the first redistribution substrate 20. The conductive posts 30 may be spaced apart from each other in the first direction D1. Each of the conductive posts 30 may further include a first pad 31 connected to an end thereof. The conductive posts 30 may be formed on corresponding first redistribution patterns (e.g., corresponding first redistribution lines 23a) of the first redistribution patterns 23 and may be formed using, for example, an electroplating process.

A first semiconductor chip 100 may be mounted on the first redistribution substrate 20 and may be laterally spaced apart from the conductive posts 30 (e.g., in the first direction D1). Connection bumps 102 may be disposed on a corresponding chip pad 101 of the first semiconductor chip 100, and the connection bumps 102 may be provided on corresponding first redistribution patterns 23 (e.g., corresponding first redistribution lines 23a) of the first redistribution patterns 23.

A molding layer 50 may be formed on the first redistribution substrate 20 and may cover the conductive posts 30 and the first semiconductor chip 100. For example, the formation of the molding layer 50 may include forming a molding layer 50 which fills a space between the first semiconductor chip 100 and the conductive posts 30 and covers the conductive posts 30 and the first semiconductor chip 100, and planarizing the molding layer 50 to expose top surfaces 30U of the conductive posts 30. Due to the planarization process, the top surfaces 30U of the conductive posts 30 may be exposed, and the top surfaces 30U of the conductive posts and a top surface 50U of the molding layer may be located at the same or substantially the same height.

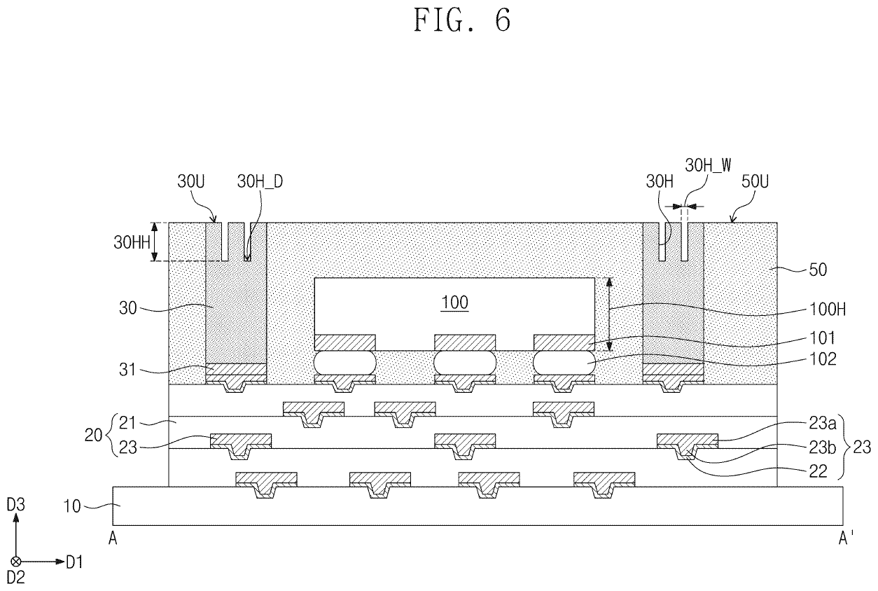

Referring to FIG. 6, contact holes 30H may be formed in the top surfaces 30U of the conductive posts 30. For example, the formation of the contact holes 30H may be performed using a wet etching process or a laser etching process. The contact holes 30H may be spaced apart from each other in the first direction D1 and the second direction D2. A ratio of a vertical thickness 30HH of each of the contact holes 30H to a width 30H_W of each of the contact holes 30H in the first direction D1 may range from 1:2 to 3:1. The vertical thickness 30HH of each of the contact holes 30H may be substantially equal to or less than a vertical thickness 100H of the first semiconductor chip 100 and may range from, for example, 1 μm to 10 μm. A bottommost surface 30H_D of each of the contact holes 30H may be located at a lower height than the top surface 30U of the conductive post 30 or the top surface 50U of the molding layer 50.

Referring again to FIGS. 1 to 3, a second redistribution substrate 40 may be formed on the first redistribution substrate 20 and the conductive posts 30. For example, the formation of the second redistribution substrate 40 may include forming a second redistribution insulating layer 41 on the lower structure 10 (more particularly, the molding layer 50 and the conductive posts 30), forming second redistribution contact holes penetrating the second redistribution insulating layer 41, forming a second redistribution seed pattern 42 which partially fills each of the second redistribution contact holes and extends onto a top surface of the second redistribution insulating layer 41, and performing an electroplating process using the second redistribution seed pattern 42 to form a second redistribution contact 43b and a second redistribution line 43a. The second redistribution contact 43b may fill a remaining portion of each of the second redistribution contact holes, and the second redistribution line 43a may extend onto the second redistribution insulating layer 41.

Second redistribution patterns (or via patterns) 43P of the second redistribution patterns 43, which correspond to the contact holes 30H, may fill the contact holes 30H. The second redistribution patterns 43P which correspond to the contact holes 30H could be referred to as via patterns. A width 43W of each of the corresponding second redistribution patterns (or via patterns) 43P in the first direction D1 may be greater than the width 30H_W of each of the contact holes 30H in the first direction D1 and may be less than a width of each of the conductive posts 30 in the first direction D1. The corresponding second redistribution patterns (or via patterns) 43P may include contact portions 40C and via contact 40V. The contact portion 40C and the via contact 40V may include the second redistribution seed pattern 42 and/or the second redistribution contact 43b of the corresponding second redistribution pattern (or via pattern) 43P. The contact portions 40C which extend from their bottom surfaces into the conductive posts 30 to fill the contact holes 30H. The contact portions 40C may be spaced apart from each other in the first direction D1 and the second direction D2 to correspond to the contact holes 30H. A vertical thickness 40C_H of each of the contact portions 40C may be substantially equal to or less than the vertical thickness 100H of the first semiconductor chip and may range from, for example, 1 μm to 10 μm.

Since the contact portions 40C fill the contact holes 30H, contact areas between the conductive posts 30 and the corresponding second redistribution patterns (or via patterns) 43P may be increased. Since the contact areas between the conductive posts 30 and the corresponding second redistribution patterns (or via patterns) 43P are increased, electrical conductivity therebetween may be improved. Thus, the semiconductor package with improved reliability may be provided, and the semiconductor package may be more easily miniaturized and may be more easily highly integrated.

A thermal management system of the semiconductor package may be improved. Thus, thermal stress of the semiconductor package may be reduced, and it is possible to reduce or prevent a delamination phenomenon of one (e.g., the lowermost second redistribution insulating layer 41L) of the second redistribution insulating layers 41 which is in contact with the conductive posts 30. As a result, reliability of an interface therebetween may be improved to provide the semiconductor package with improved reliability.

According to the inventive concepts, the semiconductor package may include the second redistribution substrate including the second redistribution patterns, the conductive post may be electrically connected to a corresponding one of the second redistribution patterns, the top surface of the conductive post may face the second redistribution substrate, the conductive post may include the contact holes extending from the top surface of the conductive post into the conductive post, and the corresponding second redistribution pattern may fill the contact holes. The contact area between the second redistribution pattern and the conductive post may be increased by the contact holes. Thus, the electrical conductivity of the semiconductor package may be improved, and the thermal stress of the semiconductor package may be reduced. As a result, the semiconductor package having excellent reliability may be provided.

The contact area between the second redistribution pattern and the conductive post may be increased to improve the thermal management system of the semiconductor package. Thus, the thermal stress of the semiconductor package may be reduced to reduce or prevent the delamination phenomenon of the second redistribution insulating layer covering the second redistribution pattern. As a result, the reliability of the interface therebetween may be improved, and thus the semiconductor package having excellent reliability may be provided.

Furthermore, the contact area between the second redistribution pattern and the conductive post may be increased to improve the electrical conductivity of the semiconductor package, and thus the semiconductor package may be easily miniaturized and may be easily highly integrated.

While the example embodiments of the inventive concepts have been particularly shown and described, it will be understood by one of ordinary skill in the art that variations in form and detail may be made therein without departing from the spirit and scope of the attached claims.

1. A semiconductor package comprising:
a first redistribution substrate comprising first redistribution patterns and first redistribution insulating layers covering the first redistribution patterns;
a conductive post on the first redistribution substrate, extending in a direction perpendicular to a top surface of the first redistribution substrate, and electrically connected to a corresponding one of the first redistribution patterns;
a first semiconductor chip on the first redistribution substrate and laterally spaced apart from the conductive post; and
a second redistribution substrate on the conductive post and the first semiconductor chip and comprising second redistribution patterns,
wherein the conductive post is electrically connected to a corresponding second redistribution pattern of the second redistribution patterns,
wherein a top surface of the conductive post faces the second redistribution substrate,
wherein the conductive post includes contact holes extending from the top surface of the conductive post into the conductive post, and
wherein the corresponding second redistribution pattern fills the contact holes.

2. The semiconductor package of claim 1, wherein the corresponding second redistribution pattern includes contact portions filling the contact holes, and
wherein the contact portions extend from a bottom surface of the corresponding second redistribution pattern into the conductive post.

3. The semiconductor package of claim 2, wherein the contact holes are spaced apart from each other in a first direction and a second direction,
wherein the contact portions are spaced apart from each other in the first direction and the second direction to correspond to the contact holes, and
wherein the first direction and the second direction are parallel to the top surface of the first redistribution substrate and intersect each other.

4. The semiconductor package of claim 3, wherein a width of each of the contact portions in the first direction is less than a width of the corresponding second redistribution pattern in the first direction.

5. The semiconductor package of claim 2, wherein a vertical thickness of each of the contact portions is substantially equal to or less than a vertical thickness of the first semiconductor chip.

6. The semiconductor package of claim 2, wherein a vertical thickness of each of the contact portions ranges from 1 μm to 10 μm.

7. The semiconductor package of claim 1, wherein a ratio of a vertical thickness of each of the contact holes to a width of each of the contact holes in a first direction ranges from 1:2 to 3:1, and
wherein the first direction is parallel to the top surface of the first redistribution substrate.

8. The semiconductor package of claim 1, wherein a width of the corresponding second redistribution pattern in a first direction is less than a width of the conductive post in the first direction, and
wherein the first direction is parallel to the top surface of the first redistribution substrate.

9. The semiconductor package of claim 8, wherein the second redistribution substrate further comprises: second redistribution insulating layers covering the second redistribution patterns, and
wherein a lowermost one of the second redistribution insulating layers is in contact with the conductive post.

10. The semiconductor package of claim 1, further comprising:
an upper substrate on the second redistribution substrate; and
a second semiconductor chip on the upper substrate,
wherein the first semiconductor chip and the second semiconductor chip are electrically connected to each other through an interconnection pattern in the upper substrate.

11. The semiconductor package of claim 1, further comprising:
a molding layer on the first redistribution substrate and covering the first semiconductor chip,
wherein the molding layer covers the conductive post, and a top surface of the molding layer is coplanar with the top surface of the conductive post.

12. The semiconductor package of claim 11, wherein a bottommost surface of each of the contact holes is at a lower height than the top surface of the molding layer.

13. A semiconductor package comprising:
a first redistribution substrate comprising first redistribution patterns and first redistribution insulating layers covering the first redistribution patterns;
a conductive post on the first redistribution substrate, extending in a direction perpendicular to a top surface of the first redistribution substrate,, and electrically connected to the first redistribution patterns;
a first semiconductor chip on the first redistribution substrate; and
a second redistribution substrate on the conductive posts,
wherein the second redistribution substrate comprises: second redistribution patterns; and second redistribution insulating layers covering the second redistribution patterns,
wherein the second redistribution patterns are electrically connected to the conductive posts,
wherein the second redistribution patterns include via patterns in contact with a corresponding conductive post, and
wherein each of the via patterns includes contact portions extending into each of the conductive posts.

14. The semiconductor package of claim 13, wherein a width of each of the t contact portions in a first direction is less than a width of each of the via patterns in the first direction, and
wherein the first direction is parallel to a top surface of the first redistribution substrate.

15. The semiconductor package of claim 13, wherein the contact portions are spaced apart from each other in a first direction and a second direction, and
wherein the first direction and the second direction are parallel to a top surface of the first redistribution substrate and intersect each other.

16. The semiconductor package of claim 15, wherein a width of each of the via patterns in the first direction is less than a width of each of the conductive posts in the first direction, and
wherein a lowermost one of the second redistribution insulating layers is in contact with the conductive posts and covers side surfaces of the via patterns.

17. The semiconductor package of claim 13, wherein a bottommost surface of each of the contact portions is at a lower height than a top surface of each of the conductive posts.

18. The semiconductor package of claim 13, wherein a vertical thickness of each of the contact portions ranges from 1 μm to 10 μm.

19. The semiconductor package of claim 13, wherein each of the conductive posts includes contact holes extending from a top surface of each of the conductive posts into each of the conductive posts, and each of the protruding portions fills a corresponding one of the contact holes.

20. The semiconductor package of claim 19, wherein the contact holes are spaced apart from each other in a first direction and a second direction, and
wherein the first direction and the second direction are parallel to a top surface of the first redistribution substrate and intersect each other.

21-22. (canceled)
